(19) United States
(12) Patent Application Publication
(10) Pub. No.: US 2026/0081587 A1
(43) Pub. Date: Mar. 19, 2026

(54) STRUCTURE WITH SWITCHABLE VOLTAGE DIVIDER AND RELATED METHOD

(71) Applicant: GlobalFoundries U.S. Inc., Malta, NY (US)

(72) Inventors: Siva Kumar Chinthu, Bangalore (IN); Sushma Nirmala Sambatur, Bangalore (IN); Devesh Dwivedi, Bangalore (IN); Suresh Pasupula, Bangalore (IN)

(21) Appl. No.: 18/888,250

(22) Filed: Sep. 18, 2024

(51) Int. Cl. H03K 17/0812; G11C 13/00; H02M 3/07

(52) U.S. Cl. CPC H03K 17/08122; G11C 13/0038; H02M 3/07

(57) ABSTRACT

Structures and methods with a switchable voltage divider and a related method are disclosed. A structure of the disclosure includes a plurality of voltage nodes each receiving one of a plurality of voltages from the charge pump. A switchable voltage divider couples the plurality of voltage nodes to an output amplifier. The switchable voltage divider includes a common node and a plurality of first stages each coupled to one of the plurality of voltage node. Each first stage includes at least one first resistor, a first PFET, and a second PFET connected in series between a corresponding one of the plurality of voltage nodes and the common node, and a third PFET connected to a junction between the first PFET and the second PFET. A second stage includes multiple second resistors and an NFET connected in series between the common node and ground.

### BACKGROUND

The present disclosure relates to a structure with a switchable voltage divider and a related method.

A charge pump circuit is a circuit that converts a direct current (DC) power source (i.e., an input voltage (Vin)) to a larger DC power source (e.g., to an output voltage (Vout) that is greater than Vin). A charge pump circuit with a single stage can convert a Vin that is equal to a positive supply voltage (VDD) to a Vout that is approximately 2*VDD or somewhat less when an electrical load is connected to the output to drive current. For example, if Vin is 1.8 V, then Vout could be approximately 3.6V or reduced to, for example, 3.0 V due to a resistive load connected to the output. Many charge pump circuits may provide distinct voltages to operate memory elements. The voltages of a charge pump are conventionally tested from within a product to maintain safe and reliable data storage. To accommodate the high voltages, test structures conventionally use transistors with correspondingly high threshold voltages. Transistors with high threshold voltages are significantly larger and thus occupy significant surface area on a product.

### SUMMARY

Aspects of the disclosure provide a structure including a plurality of voltage nodes each receiving one of a plurality of voltages; and a switchable voltage divider including: a common node; a plurality of first stages each coupled to one of the plurality of voltage nodes, wherein each first stage includes: at least one first resistor, a first P-type field effect transistor (PFET), and a second PFET connected in series between a corresponding one of the plurality of voltage nodes and the common node; and a third PFET connected to a junction between the first PFET and the second PFET; and a second stage including multiple second resistors and an N-type field effect transistor (NFET) connected in series between the common node and ground.

Further aspects of the disclosure provide a structure including: a charge pump configured to transmit one of a plurality of voltages to a memory element; a plurality of voltage nodes each receiving one of the plurality of voltages from the charge pump; and a switchable voltage divider including: a common node; a plurality of first stages each coupled to one of the plurality of voltage nodes, wherein each first stage includes: at least one first resistor, a first P-type field effect transistor (PFET), and a second PFET connected in series between a corresponding one of the plurality of voltage nodes and the common node; and a third PFET connected to a junction between the first PFET and the second PFET; and a second stage including multiple second resistors and an N-type field effect transistor (NFET) connected in series between the common node and ground; and a set of transmission gates between the second stage and the output amplifier, wherein the set of transmission gates are configured to output a sensed voltage based on a divided one of the plurality of voltages, a protection voltage, and a reference voltage.

Additional aspects of the disclosure provide a method including: receiving, on a plurality of voltage nodes of a switchable voltage divider, a plurality of voltages, wherein the switchable voltage divider includes: a common node; a plurality of first stages each coupled to one of the plurality of voltage nodes, wherein each first stage includes: at least one first resistor, a first P-type field effect transistor (PFET), and a second PFET connected in series between a corresponding one of the plurality of voltage nodes and the common node; and a third PFET connected to a junction between the first PFET and the second PFET; and a second stage including multiple second resistors and an N-type field effect transistor (NFET) connected in series between the common node and ground; and receiving, by the switchable voltage divider, a plurality of control signals; and outputting, by the switchable voltage divider in response to the control signals, a divided one of the plurality of voltages.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram of a structure and interconnected components according to embodiments of the disclosure.

FIG. 2 is a first schematic diagram of a switchable voltage divider according to embodiments of the disclosure.

FIG. 3 is an expanded schematic diagram of transmission gates within the switchable voltage divider according to embodiments of the disclosure.

FIG. 4 an illustrative flow diagram indicating an example method for operating a structure with a switchable voltage divider according to embodiments of the disclosure.

### DETAILED DESCRIPTION

A charge pump circuit is a circuit that converts a direct current (DC) power source (i.e., an input voltage (Vin)) to a larger DC power source (e.g., to an output voltage (Vout) that is greater than Vin). A charge pump circuit with a single stage can convert a Vin that is equal to a positive supply voltage (VDD) to a Vout that is approximately 2*VDD or somewhat less when an electrical load is connected to the output to drive current. For example, if Vin is 1.8V, then Vout could be approximately 3.6 V or reduced to, for example, 3.0 V due to a resistive load connected to the output. Many charge pump circuits may provide distinct voltages to operate memory elements. The voltages of a charge pump are conventionally tested from within a product to maintain safe and reliable data storage. To accommodate the high voltages, test structures conventionally use transistors with correspondingly high threshold voltages. Transistors with high threshold voltages are significantly larger and thus occupy significant surface area on a product.

In view of the foregoing, disclosed herein are embodiments of a switchable voltage divider and a related method. A structure of the disclosure includes a plurality of voltage nodes each receiving one of a plurality of voltages from the charge pump. A switchable voltage divider couples the plurality of voltage nodes to an output amplifier. The switchable voltage divider includes a common node and a plurality of first stages each coupled to one of the plurality of voltage node. Each first stage includes at least one first resistor, a first P-type field effect transistor (PFET), and a second PFET connected in series between a corresponding one of the plurality of voltage nodes and the common node. A third PFET connected to a junction between the first PFET and the second PFET. A second stage includes multiple second resistors and an N-type field effect transistor (NFET) connected in series between the common node and ground.

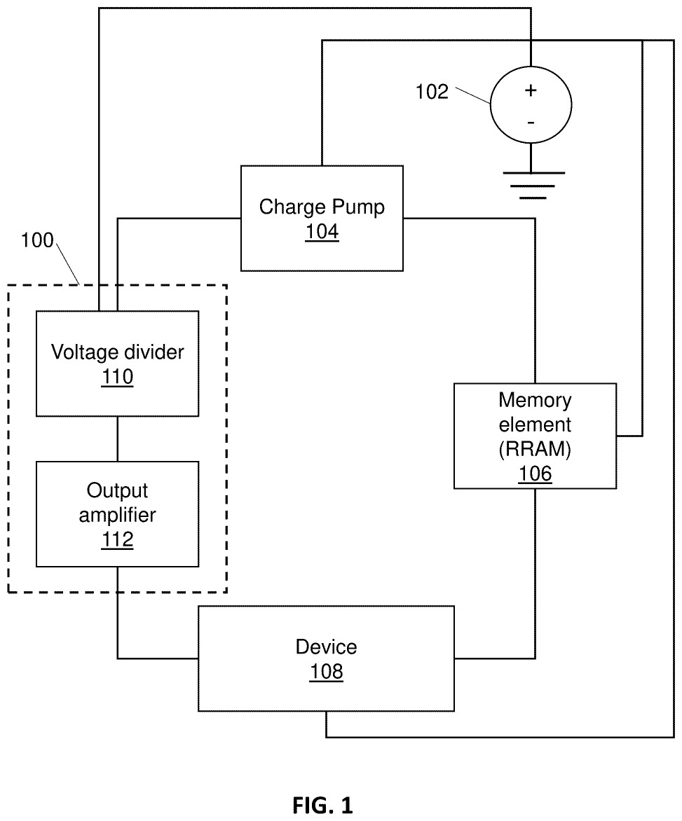

FIG. 1 provides a schematic diagram of a structure 100 according to embodiments of the disclosure with various components included therein and coupled thereto. According to various implementations, a power supply 102 may apply a voltage to a charge pump 104. Power supply 102 may include a battery and/or other voltage source on a product for electrically powering electrical functions thereof. In further embodiments, power supply 102 may include one or more external power supplies electrically coupled to the circuit(s) where structure 100 is implemented. In further implementations, power supply 102 may include a combination of batteries, external power sources, and/or other components for supplying a supply voltage (also designated as “Vdd” herein). In such cases, power supply 102 can collectively indicate all such components and/or related structures for providing a supply voltage to other components. Further details of power supply 102 are generally understood in the art and thus not discussed in further detail herein.

A charge pump 104 may be coupled between power supply 102 and structure 100, as well as between power supply 102 and a memory element 106. Charge pump 104 may include several capacitors arranged in series to convert an incoming voltage (e.g., the supply voltage from power supply 102) into a higher magnitude voltage. The various capacitors in charge pump 104 may be arranged in stages and driven via lines for transmitting clock and inverted clock signals (not shown) and control logic within or external to power supply 102, as generally understood in the art. The number of stages in charge pump 104 may determine the magnitude and/or number of higher voltages output from charge pump 104. According to various configurations, some capacitors within charge pump 104 may be coupled in parallel whereas others are coupled in series, with the connectors between individual capacitors being selected via the incoming clock signal and inverted clock signal.

According to an example, charge pump 104 may be configured to output three voltages: a first voltage (e.g., a biasing voltage for memory element 106), a second voltage (e.g., a programming voltage for memory element 106), and a third voltage (e.g., an erase voltage for memory element 106). Memory element 106 may be any one or more digital memory structures for storing and/or retrieving data in the form of binary digits (“bits”). The voltages transmitted from charge pump 104 to memory element 106 can control when and whether data in memory element 106 is stored, retrieved, erased, etc. In such cases, a biasing voltage from charge pump 104 can control whether certain transistors select specific memory elements for writing, erasing, reading, etc. The programming voltage may be a higher voltage sufficient to change the resistivity of programmable resistors in memory element 106, e.g., in the case where memory element 106 is a resistive random-access memory (RRAM) cell. In other implementations, the programming voltage may be a different voltage for changing the state of any conceivable memory element (e.g., conventional RAM, magnetic ram (“MRAM”), and/or any other or currently known or layer developed type of memory structure). The erase voltage, in the case of memory elements 106 in the form of RRAM, may be another voltage level having greater magnitude than the programming voltage and may be operable to restore a memory resistor to its original state. In other implementations, the third voltage (e.g., erase voltage) may be any other voltage level operable to remove bits from memory element 106. Memory element 106 may be coupled to a device 108 and thus may interact with device 108 to provide data to device 108 and/or to allow device 108 to modify, read, or erase data in memory element(s) 106.

Structure 100 is configured to monitor the voltages generated in charge pump 104 to confirm whether the various voltage levels sent to memory element 106 (e.g., biasing voltage, programming voltage, etc.) are of the correct magnitude. Structure 100 may be on a parallel circuit pathway such that it is coupled to charge pump 104 in parallel with memory element 106. Structure 100 also receives voltage Vdd from power supply 102. Structure 100 also may be coupled to device 108, thereby allowing device 108 to receive and/or interpret any outputs generated by structure 100 during operation. More specifically, device 108 may be electrically configured to convert output signals from structure 100, indicating the magnitude of any voltage(s) measured from charge pump 104, into data provided to a user of structure 100 and/or device 108.

Structure 100 may include a switchable voltage divider (alternatively “voltage divider” hereafter) 110 configured to receive each of the various output voltages from charge pump 104 at respective nodes as described herein. The output of voltage divider 110 may be coupled to an output amplifier 112, e.g., any currently known or later developed circuit configuration capable of converting signals received from voltage divider 110 into converted signals indicating the magnitude of voltage(s) from charge pump 104. Output amplifier 112, among other things, may operate using operational amplifiers (“op amps”) having voltage limits less than the actual voltages to be measured from charge pump 104. Hence, output amplifier 112 may receive divided, lower magnitude voltages from voltage divider 110 and correlate such voltages with their original voltage levels internally or via device 108.

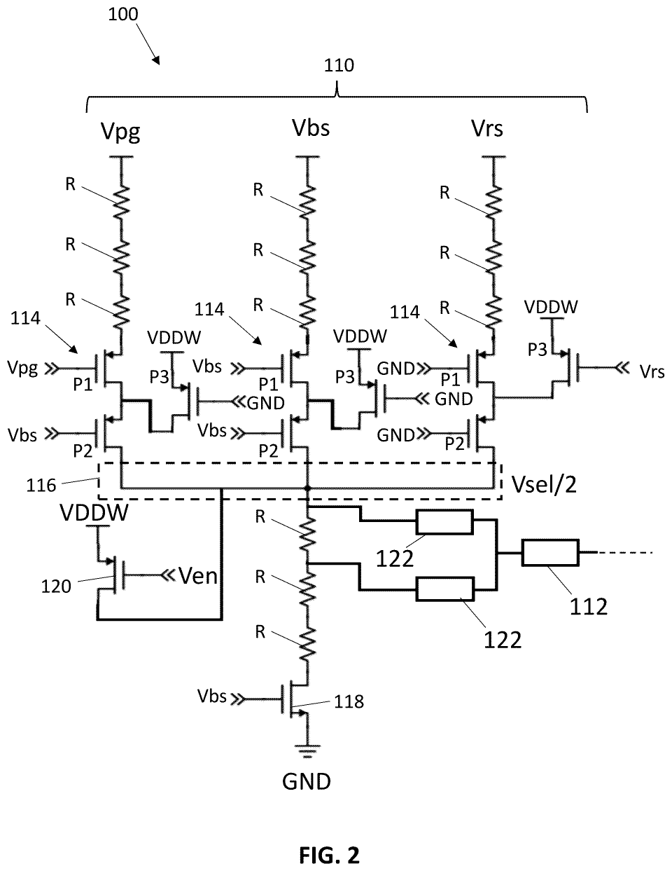

Referring to FIGS. 1 and 2 together, in which FIG. 2 provides an expanded circuit schematic representing voltage divider 110 and its components, further details of structure 100 are discussed. Voltage divider 110 may include three branches each coupled to one of a plurality of voltages from charge pump 104. The plurality of voltages, each coupled to one branch of voltage divider 110, may be described as a first voltage, second voltage, and third voltage each having a respective magnitude. The voltages applied to each branch may include a programming voltage (“Vpg”) a biasing voltage(“Vbs”) and an erase voltage (“Vrs”) as discussed herein. According to an example, Vpg may be approximately 3.0 V, Vbs may be approximately 1.8 V, and Vrs may be approximately 3.6. The voltages applied to each branch of voltage divider 110 may have different names and/or magnitudes in various further implementations, e.g., depending on the nature of memory element 106 (FIG. 1 only). Each branch may include a set of substantially identical resistors (e.g., resistors R) coupled in series between a respective voltage and a respective set of switching transistors 114. Switching transistors 114 may be configured such that only one branch is conductive at a time. Thus, the number of transistors in each switching transistor 114 may depend at least partially on the number of voltages provided to voltage divider 110.

Each group of switching transistors 114 may be arranged such that only one first stage (alternately “branch”) within voltage divider 110 is electrically conductive at a time. According to an example, switching transistors 114 each may include two p-type field effect transistors (PFETs) P1, P2 connected together at respective source and drain terminals. The drain of PFET P1 is coupled to resistors R, opposite the incoming voltage for the branch. The source of PFET P2 is coupled to a common (i.e., shared) node 116 for each branch. A third PFET P3 is coupled at its source to the interconnected source and drain of PFETs P1, P2. The drain of PFET P3 is coupled to voltage rail(s) carrying the supply voltage (“VDDW”) to voltage divider 110. All PFETs P1, P2, P3 in each group of switching transistors 114 may have the same threshold voltage, e.g., approximately 1.8 V. The threshold voltage for all PFETs in switching transistors 114 may be less than any of the plurality of voltages Vpg, Vbs, Vrs applied to voltage divider 110. Among other benefits, uniformity in threshold voltage may allow all PFETs P1, P2, P3 to be of the same or similar size. In some cases, all PFETs P1, P2, P3 may be symmetric, i.e., they do not include a long-channel or similar structure and thus may have substantially identical distances from gate to drain and gate to source. The use of similar or identically sized switching transistors 114 may enable further benefits such as avoiding the use of long channel FETs and/or similar technologies that would otherwise increase the surface area of structure 100.

Each group of switching transistors 114 may have a different set of voltages applied to the gate of PFETs P1, P2, P3, such that only one group of switching transistors 114 is conductive at a time, and thus only one of the branches is connected to common node 116. In the case of three voltages, switching transistors 114 for one branch (i.e., Vbg) may include PFET P1 coupled at its gate to Vpg, PFET P2 coupled at its gate to ground (GND), and PFET P3 coupled at its gate to Vbs. Switching transistors 114 for another branch (i.e., Vbs) may include PFET P1 coupled at its gate to Vbs, PFET P2 also coupled at its gate to Vbs, and PFET P3 coupled at its gate to ground (“GND”). Switching transistors 114 for another branch (i.e., Vrs) may include PFET P1 coupled at its gate to ground, PFET P2 also coupled at its gate to ground, and PFET P3 coupled at its gate to Vrs. In this configuration, only one of the plurality of voltages (Vpg, Vbs, Vrs) is coupled to common node 116 at a time through resistors R of a respective branch. PFET P3 may take the form of a protection transistor configured such that when PFETs P1, P2 are turned off, PFET P3 turns on and increases a voltage level at the connected source/drain terminals between PFETs P1, P2 to a heightened voltage level to prevent violations of a maximum voltage operating condition. That is, PFET P3 may increase the voltage between PFETs P1, P2 to a higher voltage when PFETs P1, P2 are turned off to prevent a floating voltage at this terminal from affecting (e.g., increasing) the voltage at common node 116 and/or creating current leakage within structure 100.

Common node 116 electrically couples each of the various branches to ground (“GND”) through a single second branch. Since switching transistors 114 only couple one of the plurality of voltages (Vpg, Vbs, Vrs) to common node 116 at a time, a set of resistors R coupling common node 116 to ground GND will be coupled to resistors R from only one of the various branches in series at a time. In this configuration, resistors R may cooperate to provide a voltage divider. The equivalent resistance of resistors R in the second branch of structure 100 may be approximately equal to the equivalent resistance of resistors R in each first branch, thereby causing the voltage at common node 116 to be approximately half of the selected voltage magnitude. The divided voltage at common node 116 is indicated as “Vsel/2” where Vsel indicates the selected voltage magnitude coupled to common node 116 through the one active set of switching transistors 114. An n-type field effect transistor (NFET) 118 may couple resistors R to ground GND, in which the gate of NFET 118 is coupled to biasing voltage Vbs, and has a threshold voltage less than biasing voltage Vbs. The threshold voltage of NFET 118 being less than biasing voltage Vbs (or whichever of the plurality of voltages is lowest) causes NFET 118 to be active simultaneously with any of switching transistors 114 and disables current flow when no switching transistors 114 are active to prevent leakage of current or voltage from structure 100.

During instances where no switching transistors 114 are active, an operator of structure 100 may wish to prevent floating voltages at common node 116. Optionally, embodiments of structure 100 may include a pull-down transistor 120 (e.g., a PFET as shown) having a gate coupled to a selectable voltage (Ven), a source coupled to common node 116, and a gate coupled to a voltage rail carrying supply voltage VDDW. Pull-down transistor 120 may serve a similar function to PFETs P3 in each set of switching transistors 114, i.e., it may set common node 116 to the magnitude of supply voltage VDDW when all switching transistors 114 are turned off. Further, where VDDW is set to zero volts (i.e., the entire device is turned off), pull-down transistor 120 may be turned on and common node 116 is also set to ground to prevent floating voltages from occurring at common node 116.

Common node 116 and various locations between resistors R in the second stage of voltage divider 110 may be coupled to output amplifier 112 through a set of transmission gates 122, e.g., two transmission gates 122 each coupled to an opposite terminal of one resistor R.

Transmission gates 122 each may be coupled to the input of output amplifier 112 to provide a differential input to output amplifier 112. Transmission gates 122 may be configured to apply a divided one of the plurality of voltages (e.g., a differential input having a voltage of one sixth the original magnitude where six resistors R are connected in series) or one of a protection voltage or a reference voltage, to output amplifier 112 as discussed in further detail herein.

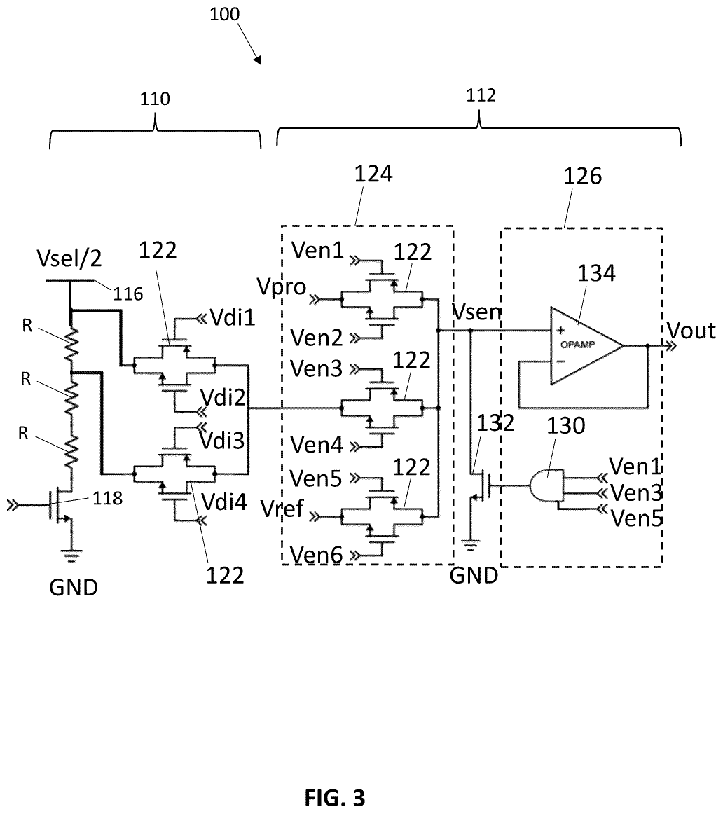

Referring now to FIGS. 2 and 3 together, further details of output amplifier 112 are discussed. Components of output amplifier 112 are shown together with interconnected portions of voltage divider 110. Transmission gates 122 each may have an input terminal coupled to one end of resistor R, such that the difference in voltage at each input to transmission gates 122 indicates the voltage across one resistor R. Although resistor R is shown to be one of three resistors between common node 116 and NFET 118, any number of resistors R may be implemented. Transmission gates may receive a set of divider enabling voltages (Vdi1, Vdi2, Vdi3, Vdi4) such that voltage signals at each terminal of resistor R will be provided to output amplifier 112 simultaneously. Output amplifier 112 may include another set of transmission gates 124 (e.g., three shown) each receiving a respective pair of enabling voltages (e.g., the pair of voltages Ven1, Ven2, the pair of voltages Ven3, Ven4, or the pair of voltages Ven5, Ven6) and an incoming voltage signal. One transmission gate 122 receives the differential voltage input from voltage divider 110, whereas the other transmission gates 122 in set of transmission gates 124 receive a protection voltage Vpro and a reference voltage Vref. Set of transmission gates 124, when active, convert the incoming differential voltage into a sensed voltage Vsen. Sensed voltage Vsen is kept within safe operating limits by being combined with protection voltage Vpro and is adjusted relative to a baseline value with reference voltage Vref via set of transmission gates 124.

Transmission gates 124 may be coupled to an amplifier stage 126 of output amplifier 112. In amplifier stage 126, some enabling voltages (Ven1, Ven3, Ven5) are input to an AND gate 130 to prevent sensed voltage Vsen from being amplified when transmission gates 124 are inactive. Specifically, AND gate 130 is coupled to the gate of a pull-down NFET 132 such that pull-down NFET will tie sensed voltage Vsen to ground when pull-down NFET 132 is turned on. When pull-down NFET 132 is turned off and thus decoupled from ground GND, a voltage amplifier 134 may convert sensed voltage Vsen to an output voltage Vout. Vout corresponds to the voltage level selected from voltage divider 110 but is within the safe operating voltage limit for all transistors in structure 100. Notably, Vout may remain at less than the maximum (i.e., breakdown) voltage for all FETs in structure 100 even where voltage divider 110 itself receives voltages that exceed the maximum voltage for any FETs in structure 100. Vout may be provided as an input to device 108 (FIG. 1), where it may be processed to determine whether the voltage(s) sensed in charge pump 104 are equal to, or different from, their desired levels for operations such as biasing, programming, and erasing.

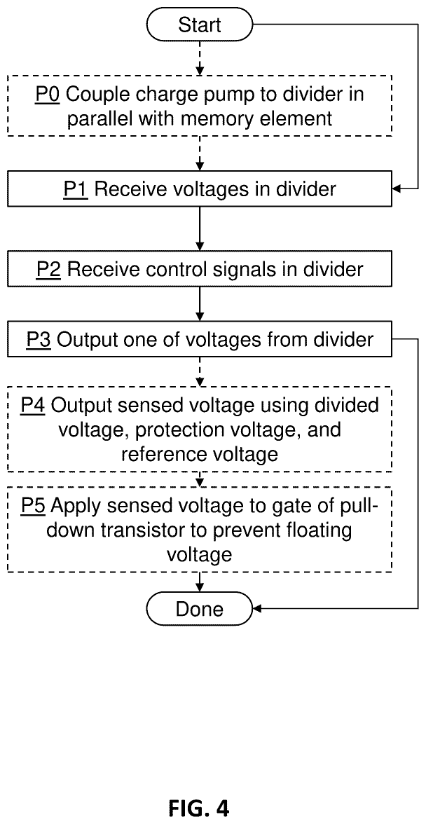

Referring now to FIGS. 1, 2, and 4, embodiments of the disclosure additionally provide methods to operate structure 100, e.g., to measure the voltage level(s) of charge pump 104 for memory element(s) 106 without exceeding the breakdown voltage of transistors in structure 100 for conducting the measurements. Initial operating phases, optionally, may include process P0 (indicated with dashed lines) of coupling charge pump 104 to voltage divider 110 in parallel with memory element 106. Structure 100 thus may be an on-product component for testing of charge pump 104, or in alternative embodiments may be part of a test structure coupled to device 108. Structure 100 thus may receive the same voltage magnitudes that are output from charge pump 104 to memory element 106. In some implementations, process P0 may be implemented in an initial phase or omitted entirely (e.g., voltage divider 110 already may be coupled to charge pump 104 in parallel with memory element 106).

In process P1, voltage divider 110 of structure 100 receives the plurality of voltages from charge pump 104 such that any one of the incoming voltages may be sensed via output amplifier 112. The method additionally may include receiving a set of control signals in voltage divider 110. The control signals received in voltage divider 110 may include, e.g., supply voltage Vddw as well as any one or more of voltages Vpg, Vrs, Vbs, and/or other voltages such as enabling voltage Ven, etc., to control which set of switching transistors 114 will couple one of the plurality of voltages to common node 116. Implementing process P2 causes only one of the incoming plurality of voltages Vpg, Vbs, Vrs to be coupled to common node 116 at a time. Common node 116 thus is set to a particular value (e.g., half of a selected voltage or “Vsel/2” in the example of FIG. 2) based on the control signals received in voltage divider 110. Common node 116 thus is set to a value derived from one of the plurality of voltages transmitted to voltage divider 110 but less than the breakdown voltage of any transistors in structure 100.

The method may include process P3 including outputting only one of the plurality of voltages from voltage divider 110 as a divided voltage. The voltage output in process P3 optionally may be transmitted to device 108 for interpretation, amplification, and/or measurement (“Done”) without further processing in structure 100 itself. In other implementations, structure 100 may include any one or more of the various additional components discussed herein.

Referring to FIG. 2-4 together, embodiments of the disclosure may include outputting sensed voltage Vsen from output amplifier 112 using the divided selected voltage from voltage divider 110 in conjunction with protection voltage Vpro and reference voltage Vref. As discussed herein, set of transmission gates 124 may act as a mixing circuit to prevent the divided voltage from exceeding a breakdown voltage of any transistors in structure 100, and by setting the voltage output relative to a reference value to enable electrical comparison and calculating of the divided voltage. In process P5, the sensed voltage optionally may be applied to the gate of pull-down NFET 132 to deactivate pull-down NFET 132, thereby causing sensed voltage Vsen to be amplified as output voltage Vout instead of being tied to ground through pull-down NFET 132. The method may conclude (“Done”) thereafter. In other implementations, processes P4 can be replicated and/or substituted in other currently known or later developed amplifier structures for measuring a divided output voltage from voltage divider 110. Thus, embodiments of the disclosure in some cases may include only voltage divider 110 of structure 100 and/or processes P1-P3 discussed herein.

Embodiments of the disclosure provide various technical and commercial advantages, examples of which are discussed herein. Embodiments of structure 100 and related methods enable measuring and/or comparing of sensed voltages to desired levels, particularly from charge pump(s) 104, without implementing higher-threshold transistors. The use of transistors with lower threshold voltages reduces surface area requirements relative to similar circuits and/or methods to sense the magnitude of voltage outputs for a component such as charge pump 104. Embodiments of the disclosure also avoid the use of biasing circuits and/or level shifters that may otherwise be needed to enable the use of transistors with lower voltage thresholds. Embodiments of the disclosure provide these technical benefits without meaningfully sacrificing speed and/or accuracy when implemented in conjunction with device(s) 108 that rely on memory element(s) 106 with multiple high magnitude voltage signals (e.g., 1.8 V or more).

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a plurality of voltage nodes each receiving one of a plurality of voltages; and
a switchable voltage divider including:
a common node;
a plurality of first stages each coupled to one of the plurality of voltage nodes, wherein each first stage includes: at least one first resistor, a first P-type
field effect transistor (PFET), and a second PFET connected in series between a corresponding one of the plurality of voltage nodes and the common node; and a third PFET connected to a junction between the first PFET and the second PFET; and
a second stage including multiple second resistors and an N-type field
effect transistor (NFET) connected in series between the common node and ground.

2. The structure of claim 1, wherein the third PFET in each of the plurality of first stages is a protection transistor coupled to a voltage rail, and in response to the first PFET and the second PFET being turned off, the protection transistor turns on and increases a voltage level at the junction between the first PFET and the second PFET to prevent violations of maximum voltage operating conditions.

3. The structure of claim 1, wherein the plurality of voltage nodes includes:
a first voltage node at a first positive voltage level,
a second voltage node at a second positive voltage level less than the first positive voltage level, and
a third voltage node at a third positive voltage level between the first positive voltage level and the second positive voltage level.

4. The structure of claim 1, wherein each PFET in the plurality of first stages is symmetric.

5. The structure of claim 1, further comprising a set of transmission gates between the second stage and an output amplifier, wherein the set of transmission gates are configured to output a sensed voltage based on a divided one of the plurality of voltages, a protection voltage, and a reference voltage.

6. The structure of claim 1, wherein the switchable voltage divider is coupled to the plurality of voltage nodes in parallel with a memory element.

7. The structure of claim 1, wherein the switchable voltage divider further includes a pull-down transistor coupled to the common node, the pull-down transistor configured to prevent a floating voltage at the common node.

8. A structure comprising
a plurality of voltage nodes each receiving one of the plurality of voltages from a charge pump; and
a switchable voltage divider including:
a common node;
a plurality of first stages each coupled to one of the plurality of voltage nodes, wherein each first stage includes: at least one first resistor, a first P-type
field effect transistor (PFET), and a second PFET connected in series between a corresponding one of the plurality of voltage nodes and the common node; and a third PFET connected to a junction between the first PFET and the second PFET; and
a second stage including multiple second resistors and an N-type field effect transistor (NFET) connected in series between the common node and ground; and
a set of transmission gates coupled to the second stage, wherein the set of transmission gates are configured to output a sensed voltage based on a divided one of the plurality of voltages, a protection voltage, and a reference voltage.

9. The structure of claim 8, wherein the third PFET in each of the plurality of first stages is a protection transistor coupled to a voltage rail, and in response to the first PFET and the second PFET being turned off, the protection transistor turns on and increases a voltage level at the junction between the first PFET and the second PFET to prevent violations of maximum voltage operating conditions.

10. The structure of claim 8, wherein the plurality of voltage nodes includes:
a first voltage node at a first positive voltage level,
a second voltage node at a second positive voltage level less than the first positive voltage level, and
a third voltage node at a third positive voltage level between the first positive voltage level and the second positive voltage level.

11. The structure of claim 8, wherein each PFET in the plurality of first stages is symmetric.

12. The structure of claim 8, wherein the switchable voltage divider is coupled to the plurality of voltage nodes in parallel with a memory element.

13. The structure of claim 8, wherein the switchable voltage divider further includes a pull-down transistor coupled to the common node, the pull-down transistor configured to prevent a floating voltage at the common node.

14. A method comprising:
receiving, on a plurality of voltage nodes of a switchable voltage divider, a plurality of voltages, wherein the switchable voltage divider includes:
a common node;
a plurality of first stages each coupled to one of the plurality of voltage nodes, wherein each first stage includes: at least one first resistor, a first P-type
field effect transistor (PFET), and a second PFET connected in series between a corresponding one of the plurality of voltage nodes and the common node; and a third PFET connected to a junction between the first PFET and the second PFET; and
a second stage including multiple second resistors and an N-type field
effect transistor (NFET) connected in series between the common node and ground; and
receiving, by the switchable voltage divider, a plurality of control signals; and
outputting, by the switchable voltage divider in response to the control signals, a divided one of the plurality of voltages.

15. The method of claim 14, wherein the third PFET in each of the plurality of first stages is a protection transistor coupled to a voltage rail, and the method further includes turning on the protection transistor in response to the first PFET and the second PFET being turned off to increase a voltage level at the junction between the first PFET and the second PFET to prevent violations of a maximum voltage operating condition.

16. The method of claim 14, wherein the plurality of voltage nodes includes:
a first voltage node at a first positive voltage level,
a second voltage node at a second positive voltage level less than the first positive voltage level, and
a third voltage node at a third positive voltage level between the first positive voltage level and the second positive voltage level.

17. The method of claim 14, wherein each PFET in the plurality of first stages is symmetric.

18. The method of claim 14, wherein the voltage divider further includes a set of transmission gates coupled to the second stage, wherein the set of transmission gates are configured to output a sensed voltage based on a divided one of the plurality of voltages, a protection voltage, and a reference voltage.

19. The method of claim 14, further comprising coupling the switchable voltage divider to the plurality of voltage nodes in parallel with a memory element.

20. The method of claim 14, further comprising applying a voltage to a gate of a pull-down transistor coupled to the common node, wherein the pull-down transistor is configured to prevent a floating voltage at the common node.
